(19) United States
(12) Patent Application Publication
(10) Pub. No.: US 2024/0396290 A1
(43) Pub. Date: Nov. 28, 2024

(54) INFRARED EMITTER PACKAGE

(71) Applicants: Jin-Shown Shie, Hsinchu County (TW); Precision Sensors Design Inc., Hsinchu (TW)

(72) Inventors: Jin-Shown SHIE, Hsinchu County (TW); Joseph Weng, New Taipei City (TW); Tsai-Sen Lin, Zhubei City (TW); Hsiang-Chih Meng, Taipei City (TW); Shou-Jing Yu, Taipei City (TW)

(73) Assignees: Jin-Shown Shie, Hsinchu County (TW); Precision Sensors Design Inc., Hsinchu (TW)

(21) Appl. No.: 18/321,501

(22) Filed: May 22, 2023

(51) Int. Cl. H01S 5/0225; H01S 5/02212; H01S 5/02345

(52) U.S. Cl. CPC H01S 5/0225; H01S 5/02212; H01S 5/02345; H01S 5/183; H01S 2302/00

(57) ABSTRACT

An IR emitter package includes a TO-can unit, a light emitting diode (LED), and an infrared (IR) emitting unit. The TO-can unit includes a header plateau that has top and bottom sides and a hole extending through top and bottom sides. A first connection pin extending through the hole has a top end exposed from a center region of the top side surrounding the hole. The second connection pin is electrically insulated from the first connection pin. The LED is disposed on the center region and directly electrically connects the top end of the first connection pin. The IR emitting unit includes a membrane above a cavity that is aligned with and encompasses the center region of the header plateau to receive the LED. The LED has a bonding pad, and a connecting wire connecting the bonding pad to an electrical connecting site within the cavity on the header plateau.

### FIELD

The disclosure relates to an infrared emitter package, and more particularly to an infrared (IR) emitter package having a vertical cavity surface emission laser diode for emission of infrared light to a light absorbing film.

### BACKGROUND

An infrared (IR) emitter of MEMS (micro-electro-mechanical system) type such as the one disclosed in U.S. Pat. No. 11,004,997B2 and shown in FIG. 1, is fabricated via backside bulk micromachining on a silicon wafer 71, and has a cavity 61 and a floating membrane 62 including a light absorber 623. A light emitting diode chip (LED) 8 is disposed on a support substrate 9, and is located below the floating membrane 62. In the IR emitter, light emitted by the LED chip 8 is absorbed by the floating membrane 62, resulting in the floating membrane 62 being heated and emitting light that is mostly in the infrared spectrum. However, the IR emitter may yet be further improved by optimizing a structure for packaging the IR emitter, an electrical connection arrangement for driving the lighting source, and the type of lighting source.

One choice of packaging for mounting the IR emitter is a conventional TO (transistor outline) package. The conventional TO package generally has a TO-metal can header plate and at least two lead pins protruding downwardly from the TO-metal can header plate. The IR emitter is typically mounted over a top surface of the TO-metal can header plate. However, because the LED chip 8 is within the cavity 61 of the IR emitter, if the conventional TO-metal can header is used for packaging the IR emitter disclosed in the afore-mentioned U.S. Pat. No. 11,004,997B2, three or more wire connections would be needed to electrically connect the LED chip 8 to the lead pins of the TO-metal can header in order to circumvent the IR emitter mounted over the LED chip 8 so that the wire connections would not interfere with the IR emitter. Due to the need of extra wire connections, the packaging of the IR emitter would be costly and labor intensive.

### SUMMARY

Therefore, an object of the disclosure is to provide an infrared emitter package that can alleviate at least one of the drawbacks of the prior art.

According to the disclosure, an infrared emitter package includes a TO-can unit, a vertical cavity surface emission laser (VCSEL) diode, and an infrared (IR) emitting unit. The TO-can unit includes a header plateau, a first connection pin, and a second connection pin. The header plateau is metallic and has a top side, a bottom side that is opposite to the top side, and a hole penetrating through the top and bottom sides. The top side has a center region surrounding the hole, and an electrical connecting site that is disposed on the top side. The first connection pin extends through the hole of the header plateau, protrudes downwardly from the bottom side, is electrically insulated from the header plateau by an insulating material filled in the hole, and has a top end exposed from the top side. The second connection pin protrudes downwardly from the bottom side, is electrically insulated from the first connection pin, and is electrically conductive to the electrical connecting site. The VCSEL diode is disposed on the center region of the top side of the header plateau and directly and electrically connecting the top end of the first connection pin. The VCSEL diode has a bonding pad, and a connecting wire that connects the bonding pad to the electrical connecting site. The infrared emitting unit includes a substrate and a membrane. The substrate is disposed on the top side of the header plateau and has a cavity disposed above and aligned with the center region of the top side so as to encompass the center region. The cavity receives the VCSEL diode and the electrical connecting site and efficiently collects the light emitted by the VCSEL diode. The membrane is stacked on the substrate and has a light-absorbing film above the cavity for absorbing light emitted by the VCSEL diode efficiently and re-emitting the light as heat by a non-radiative recombination mechanism so as to be heated up to an elevated temperature and generate infrared radiation.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view of a prior art infrared emitter disclosed in U.S. Pat. No. 11,004,997B2.

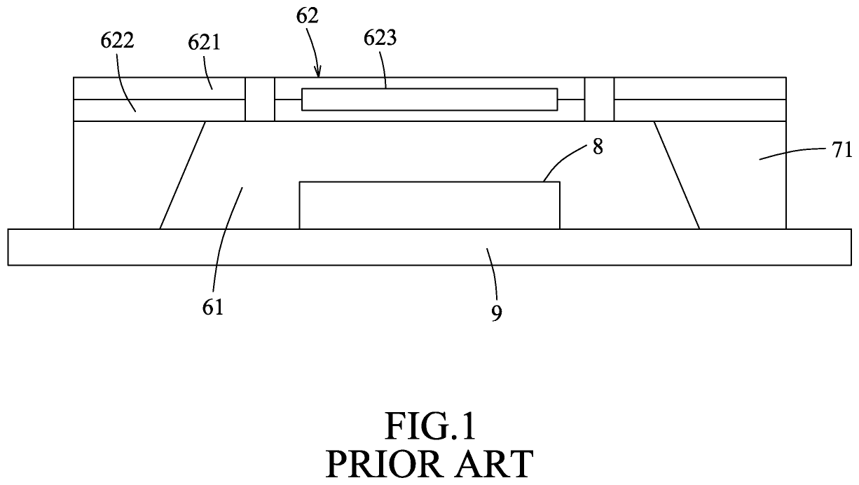

FIG. 2 is a schematic cross-sectional view of a first embodiment of an infrared (IR) emitter package according to the present disclosure.

FIG. 3 is a graph showing the variation of temperature over time recordings of Model #1 of the IR emitter package used in a simulation experiment.

FIG. 4 is a graph showing the variation of temperature over time recordings of Model #2 of the IR emitter package used in the simulation experiment.

FIG. 5 is a schematic cross-sectional view illustrating a lens disposed at a top window opening of a top cap of a TO-can unit of the IR emitter package.

FIG. 6 is a schematic cross-sectional view illustrating another lens disposed at the top window opening of the TO-can unit.

FIGS. 7a to 7e show consecutive steps for assembling the infrared emitter package.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

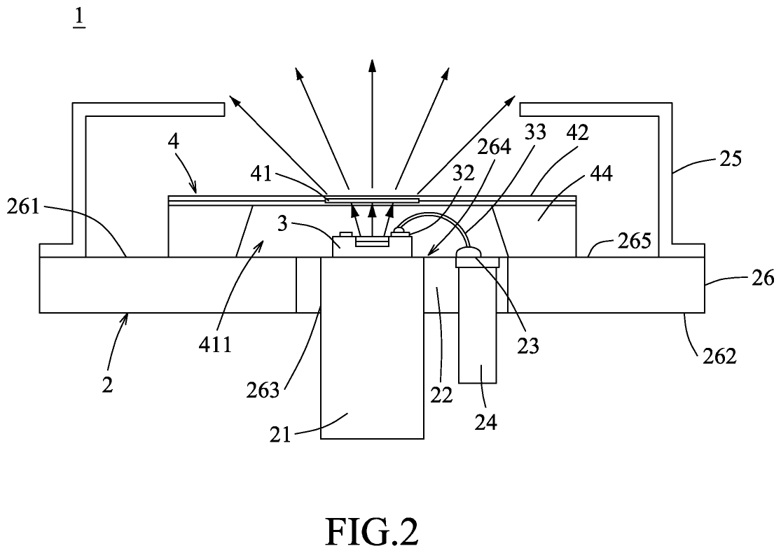

Referring to FIG. 2, an embodiment of the infrared emitter package 1 according to the present disclosure includes a TO-can unit 2, a vertical cavity surface emission laser (VCSEL) diode 3 with a small emission angle, and an infrared (IR) emitting unit 4. In this embodiment, the TO-can unit 2 is used as a package device to mount and electrically connect the VCSEL diode 3. The IR emitting unit 4 is similarly mounted to the TO-can unit 2, in a position above the VCSEL diode 3 so as to receive light emitted by the VCSEL diode 3.

The TO-can unit 2 includes a header plateau 26, a first connection pin 21, a second connection pin 24, and a top cap 25. The header plateau 26 is metallic and has a top side 261, a bottom side 262 that is opposite to the top side 261, and a hole 263 penetrating through the top and bottom sides 261, 262. The top side 261 has a center region 264 surrounding the hole 263, an outer region 265 surrounding the center region 264, an electrical connecting site 23 that is disposed on the center region 264 of the top side 261 and is located inside the cavity 441 on the center region 264.

The first connection pin 21 is electrically conductive and extends through the hole 263 of the header plateau 26, protrudes downwardly from the bottom side 262, and has a top end exposed from the top side 261 of the header plateau 26. The second connection pin 24 protrudes downwardly from the bottom side 262, is electrically isolated from the first connection 21 and is electrically conductive to the electrical connecting site 23. The VCSEL diode 3 is disposed on the center region 264 of the top side 261 of the header plateau 26 and is directly and electrically connecting the top end of the first connection pin 21, and has a bonding pad 32, and a connecting wire 33 that connects the bonding pad 32 to the electrical connecting site 23. In this embodiment, the VCSEL diode 3 is die attached to the top end of the first connection pin 21 of the TO-can unit 2, while being wire bonded to the electrical connecting site 23 on the header plateau 26.

The IR emitting unit 4 includes a substrate 44 that is disposed on the top side 261 of the header plateau 26 and has a cavity 411 disposed above and aligned with the center region 264 of the top side 261 so as to encompass the center region 264 and receive the VCSEL diode 3 within. The cavity 411 receives and collects the light emitted by the VCSEL diode 3 efficiently. It should be noted that the connecting wire 33 of the VCSEL diode 3 and the electrical connecting site 23 of the header plateau 26 are located on the center region of the top side 261 of the header plateau 26, and therefore, they are also received within the cavity 411. The IR emitting unit 4 further includes a membrane 42 that is stacked on the substrate 44 and that has a high efficiency light absorbing film 41 above the cavity 411 for efficiently absorbing light emitted by the VCSEL diode 3 and re-emitting the light as heat by a non-radiative recombination mechanism so as to be heated up to an elevated temperature and generate infrared radiation as that of a traditional incandescent filament lamp.

In this embodiment, the header plateau 26 is metallic, and the first connection pin 21 is electrically insulated from the header plateau 26 by an insulating material 22 filled in the hole 263. The insulating material 22 that is used to fill in the hole 263 is an electrically insulating glass material. However, in other embodiments, other electrically insulating materials may be used, such as a ceramic material or a polymer material.

Referring back to FIG. 2, the second connection pin 24 penetrates the header plateau 26 and has a top end exposed from the center region 264 of the top side 261 of the header plateau 26. The electrical connecting site 23 is disposed on the top end of the second connection pin 24. The VCSEL diode 3 is die attached to the top end of the first connection pin 21 of the TO-can unit 2, while being wire bonded to the electrical connecting site 23.

The embodiment shown in FIG. 2 may be implemented by connecting the first and second connection pins 21, 24 to a power supply to form a closed loop. The first connection pin 21 may be a negative pin, and the second connection pin 24 may be a positive pin. In some embodiments, the first connection pin 21 is located at a center of the center region 264 of the top side 261 of the header plateau 26 so that the VCSEL diode 3 is situated at the center. The second connection pin 24 is offset from the center of the center region 264. In some embodiments, the first connection pin 21 is located in close proximity to the center of the center region 264 so that the VCSEL diode 3 is situated in close proximity to the center. The second connection pin 24 is farther from the center than the first connection pin 21.

By virtue of the electrical connecting site 23 being located in the center region 264 of the top side 261 which is encompassed by the cavity 411 of the IR emitter unit 4, the bonding wire 33 of the VCSEL diode 3 is allowed to connect the electrical connecting site 23 inside the cavity 411 and does not interfere with the membrane 42 disposed above the cavity 411. The electrical connecting site 23 is electrically connected to the second connection pin 24 as it is directly formed on the top end of the second connection pin 24 in FIG. 2. However, the connection between the second connection pin 24 and the electrical connecting site 23 illustrated by way of the example in FIG. 2 is not a limitation of the TO can unit 2, and there may be in other configurations. For example, the header plateau 26 and the second connection pin 24 of the TO-can unit 2 may be made from a same conductive metallic material, such as nickel, and the electrical connecting site 23 may be a part of the center region 264 of the top side 261 of the header plateau 26. The VCSEL diode 3 used in this embodiment has a smaller vertical emission angle and is able to create a very small incident area on the light absorbing film 41 of the membrane 42 of the IR emitting unit 4, thus allowing the light absorbing film 4 to be made smaller while absorbing most of the laser light. Additionally a smaller light absorbing film 4 will have a smaller IR emission area and allow the IR emitting unit 4 to have better optical beam collimation.

In one embodiment of the disclosure, the VCSEL diode 3 has a vertical emission angle that is not larger than 30 degrees, and emits a wavelength that ranges from 650 nm to 950 nm and that is able to be absorbed by polycrystalline semiconductor materials, such as polycrystalline silicon, germanium, silicon carbide, etc. In other embodiments, the VCSEL diode 3 has a vertical emission angle that is not larger than 27 degrees, or 25 degrees, The smaller vertical emission angle means the power of the VCSEL diode 3 is focused in a smaller area and therefore allows the membrane 42 of the IR emitting unit 4 to have a smaller light absorbing film 41 for the same amount of energy emitted from the beam of the VCSEL diode 3. Under the same light excitation power source, the light absorbing film 41 with a smaller film size can absorb more light, and thus can be heated to a higher temperature to produce higher IR radiation power based on the Stephan-Boltzmann law and Plank's law of blackbody radiation.

The light absorbing film 41 has a film size slightly larger than that of a cross section of a laser beam of the VCSEL diode 3 intercepted by the light absorbing film 41 to ensure the light absorbing film 41 will have a high absorption efficiency and faster thermal response time. In addition, thermal mass of the light absorbing film 41 will also be minimized. In some embodiments, the VCSEL diode 3 has a vertical emission angle (8) not larger than 30°, and the light absorbing and re-emission film (i.e., the light absorbing film 41) has a film size 10% larger than that of a cross section of a laser beam of the VCSEL diode 3 intercepted by the light absorbing film 41. In other embodiments, the light absorbing film 41 has a film size smaller than 1000 nm×1000 nm based on the experiment data. In other embodiments, the light absorbing film 41 has a film size not larger than 1 mm². The light absorbing film 41 may be selected from a GE film and a Si—Ge film which are low pressure chemical vapor deposited (LPCVD) and which have a narrow energy gap to provide a high optical absorption of a wavelength emitted by the VCSEL diode. In one embodiment, the light absorbing film 41 has a high optical absorption of a wavelength of 850 nm emitted by the VCSEL diode 3.

TABLE 1

| | | Input | | | |
|---|---|---|---|---|---|
| | Input | pulse | Peak | 10-90% | 90-10% |
| | power | width | Temp. | Rise time | Fall time |
| Dimensions(μm) | (mW) | (msec) | (C.) | (msec) | (msec) |
| 1000 × 1000 | 100 | 1 | 93.114 | 0.8 | 2.6 |
| 100 × 100 | 100 | 1 | 375.47 | 0.3 | 0.3 |
| 1000 × 1000 | 300 | 1 | 229.34 | 0.8 | 2.6 |
| 100 × 100 | 300 | 1 | 1074.6 | 0.3 | 0.3 |
| 10000 × 1000 | 1000 | 1 | 706.08 | 0.8 | 2.6 |
| 100 × 100 | 1000 | 1 | 3418.1 | 0.3 | 0.3 |

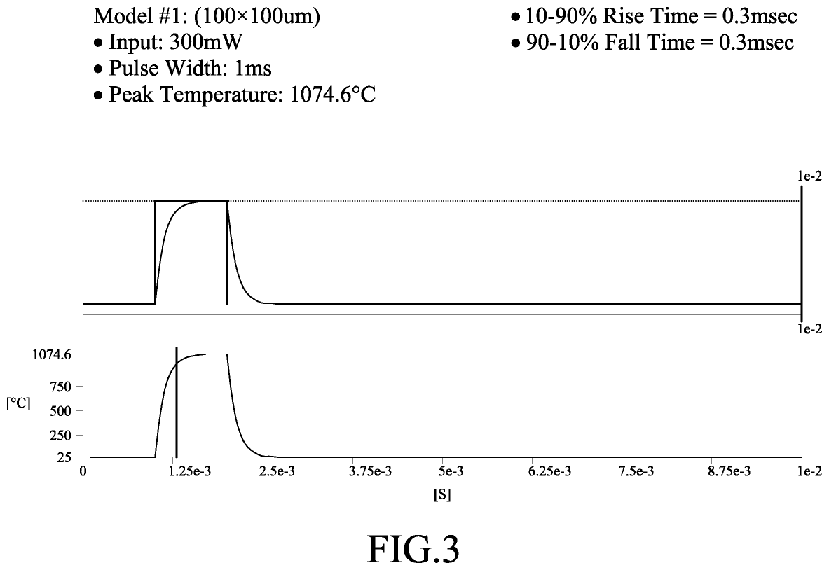

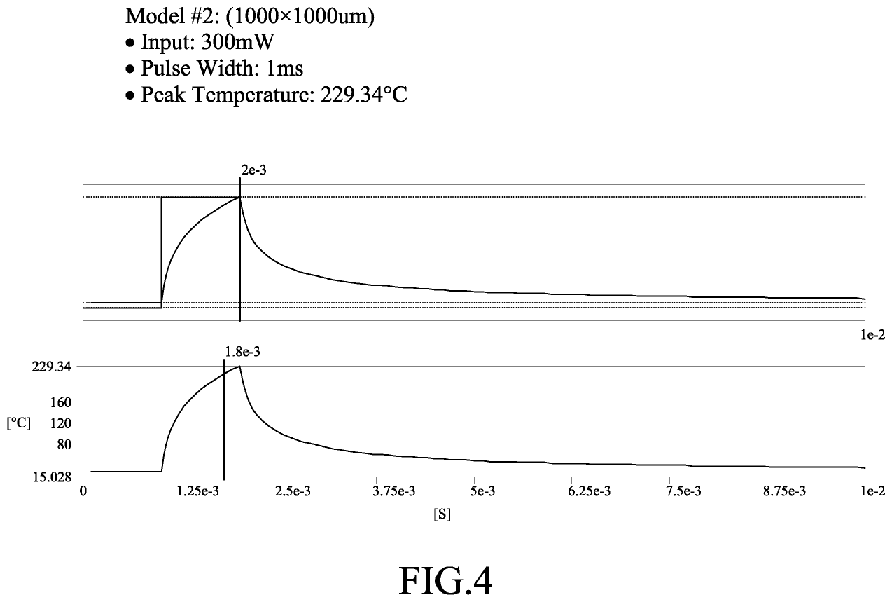

A simulation experiment was conducted with two models of the infrared emitter package of the disclosure that are labelled Model #1 and Model #2, respectively. The results of the experiment are shown in Table 1 and FIGS. 3 and 4. The only difference between the two models is in the dimensions of the light absorbing film 41, with Model 1 having dimensions of 100×100 μm and Model 2 having dimensions of 1000×1000 μm. The experiment measured the variation of temperature over time for the two models, and was conducted at 100 mW, 300 mW and 1000 mW input power settings for a VCSEL diode while keeping the input pulse width constant at 1 msec. From the results of Table 1 it can be observed that Model #1 has higher peak temperatures and shorter 10-90% rise times and 90-10% fall times at all three input power settings compared to Model #2. FIGS. 3 and 4 are temperature variation over time graphs at 300 mW input power plotted from the data in Table 1. Here the 10-90% rise time difference and 90-10% fall time difference between Model #1 and Model #2 can be seen more clearly; additionally, it may be observed from FIGS. 3 and 4 that Model #1 reaches its peak temperature much more rapidly and remains at its peak temperature for a much longer period. In conclusion, the experiment showed that Model #1 with the smaller light absorbing film 41 has a higher thermal response speed and a higher peak temperature.

The above experiment demonstrates that a smaller light emission area provides a faster thermal response speed. It is known that the thermal response speed can limit an optical chopping rate, since an optical chopping rate cannot exceed the thermal response speed. As the thermal response speed of the IR emitting unit 4 is faster, it allows a faster optical chopping rate which greatly favors sensor noise reduction during signal processing. In addition, the smaller light emission area provides better optical beam collimation, which projects advantageously a smaller spot and stronger beam intensity to a distant IR sensor, such as to an NDIR detection module, which may be able to detect a stronger signal.

The infrared emitter package 1 which includes the IR emitting unit 4 with a relatively small absorbing film size is very suitable for application to nondispersive infrared (NDIR) sensors. NDIR sensors use optical measurements to detect gasses instead of chemical reactions. In general, NDIR sensors have a gas chamber to contain a gas to be detected, an IR emitter disposed at one side of the gas chamber to emit an IR radiation containing a signature, or characteristic wavelength of the gas to be detected, and a detector together with an IR filter disposed on the other side of the gas chamber to respond to the gas to be detected in the chamber. The IR radiation from the IR emitter passes through the chamber and reaches the detector. The signature wavelength of the IR radiation emitted by the IR emitter attenuates when the concentration of the gas under detection increases in the chamber. This is then measured by the detector of the NDIR sensor.

By virtue of having a faster thermal response speed and thus a higher optical chopping rate of the IR emitting unit 4, when the IR emitter package 1 is used in the NDIR sensor, an improved signal to noise ratio (SNR) may be achieved. Referring back to FIG. 3, the top cap 25 of the header plateau 26 is attached to the top side 261 of the header plateau 26 to cover and protect the IR emitting unit 4. The top cap 25 has a top window opening 251 that allows passage of the radiation emitted by the IR emitting unit 4. The top cap 25 may further have a transparent plate disposed on the window opening 251 as protection against contamination from the external environment.

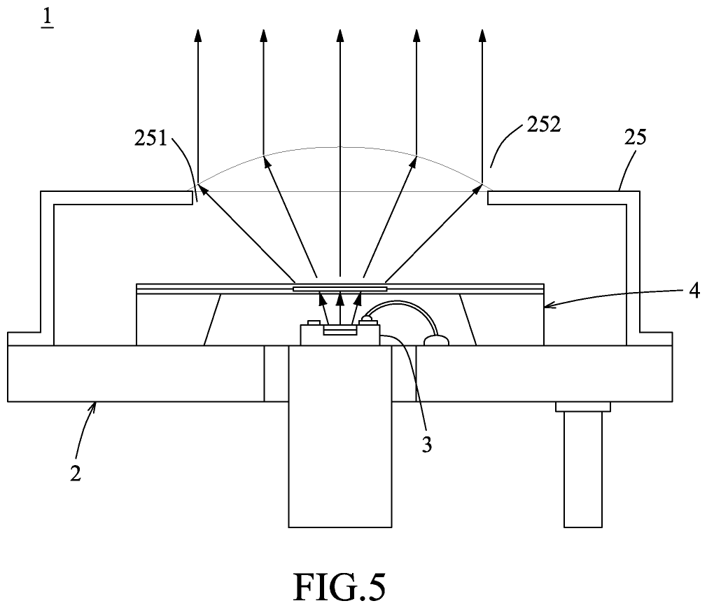

In some embodiments, the infrared emitter package 1 is used for an NDIR sensor. Referring to FIG. 5, in the infrared emitter package 1 for use in an NDIR sensor, the top cap 25 has a lens 252 that is transparent to a signature wavelength of a gas to be detected by the NDIR sensor and is disposed at the top window opening 251 for collimating the signature wavelength. The radiation emitted by the IR emitting unit 4 contains the signature wavelength of the gas. For example, in this embodiment, the NDIR sensor is setup to detect CO₂ gas, and the gas signature wavelength is 4.26 μm.

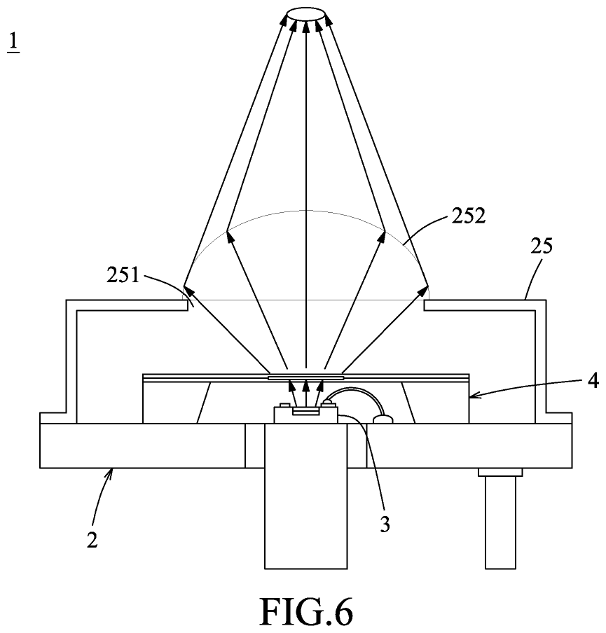

Referring to FIG. 6, in another embodiment, a lens 253 disposed at the top window opening 251 of the top cap 25 is also transparent to the signature wavelength of the gas to be detected, but the lens 253 in this embodiment is for focusing the signature wavelength of the gas to be detected.

When the infrared emitter package 1 of the disclosure is used in an NDIR sensor and the lens 252 or 253 is coated with a filter material, the NDIR sensor may dispense with an IR filter that is usually needed for placement in front of a detector, because the lens 252 or 253 may already have the functionality of the IR filter.

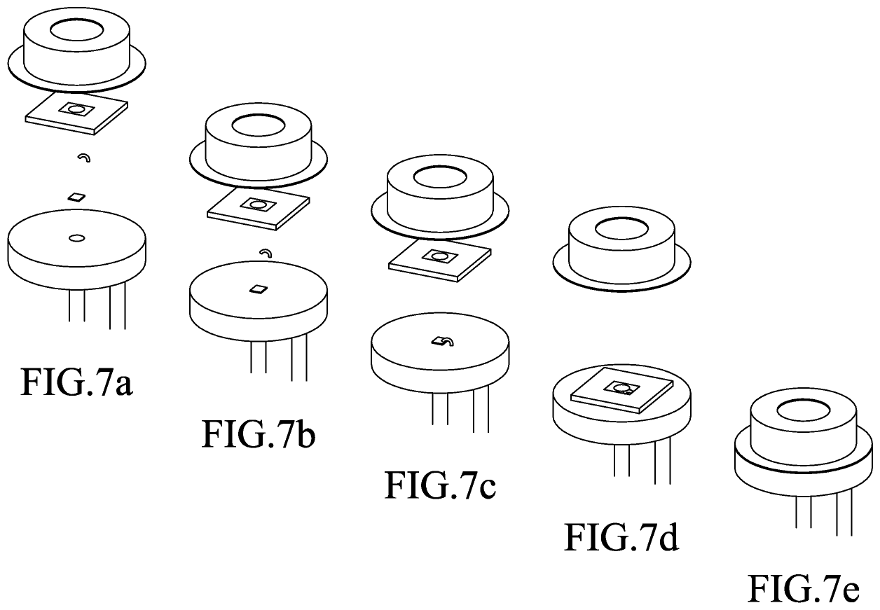

FIGS. 7a to 7e, shows an assembly procedure of the infrared emitter package 1 according to the present disclosure. First the VCSEL diode 3 is die attached to the top end of the first connection pin 21. Next, the VCSEL diode 3 is wire bonded from the bonding pad 32 of the VCSEL diode 3 to the electrical connecting site 23 on the center region of the top side 261 of the header plateau 26. Then, the IR emitting unit 4 is placed over the VCSEL diode 3 so that the center region of the top side 261 of the header plateau 26 is aligned with and encompassed by the cavity 411 of the substrate 44, and then the IR emitting unit 4 is lowered to cover over the VCSEL diode 3 on the header plateau 26. At this stage, the top end of the first connection pin 21 is already directly and electrically connected to the VCSEL diode 3 which is now received in the cavity 411 of the substrate. Finally, the top cap 25 is arc welded on the header plateau 26 which protects

By virtue of the VCSEL diode 3 having a small vertical emission angle and the light absorbing film 41 that is used to intercept the laser beam of the VCSEL diode 3 may have a smaller film size, a high absorption efficiency, and a faster thermal response time. Additionally, it should be noted that the infrared emitter package 1 according to the present disclosure has a small heated area that ensures that the thermal mass will be minimized and a faster thermal response time will be achievable.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An infrared emitter package comprising:
a TO-can unit including a header plateau that is metallic and that has a top side, a bottom side that is opposite to said top side, and a hole penetrating through said top and bottom sides, said top side having a center region surrounding said hole, and an electrical connecting site that is disposed on said top side,
a first connection pin extending through said hole of said header plateau, protruding downwardly from said bottom side, being electrically insulated from said header plateau by an insulating material filled in said hole, and having a top end exposed from said top side, and
a second connection pin protruding downwardly from said bottom side, being electrically isolated from said first connection pin, and being electrically conductive to said electrical connecting site,
a vertical cavity surface emission laser (VCSEL) diode disposed on said center region of said top side of said header plateau and directly and electrically connecting said top end of said first connection pin, said VCSEL diode having a bonding pad, and a connecting wire that connects said bonding pad to said electrical connecting site; and
an infrared (IR) emitting unit including
a substrate that is disposed on said top side of said header plateau and that has a cavity disposed above and aligned with said center region of said top side so as to encompass said center region, said cavity receiving said VCSEL diode and said electrical connecting site and efficiently collecting the light emitted by said VCSEL diode, and
a membrane that is stacked on said substrate and that has a light-absorbing film above said cavity for absorbing light emitted by said VCSEL diode efficiently and re-emitting the light as heat by a non-radiative recombination mechanism so as to be heated up to an elevated temperature and generate infrared radiation.

2. The infrared emitter package as claimed in claim 1, wherein said vertical-cavity surface-emitting laser (VCSEL) diode emits a wavelength ranging from 650 nm to 950 nm that is able to be absorbed by a polycrystalline Germanium semiconductor material.

3. The infrared emitter package as claimed in claim 1, wherein said light absorbing film has a film size slightly larger than that of a cross section of a laser beam of said VCSEL diode that is intercepted by said light absorbing film to ensure a high absorption efficiency, a minimized thermal mass and a faster thermal response time of said light absorbing film.

4. The infrared emitter package as claimed in claim 1, wherein said VCSEL diode has a vertical emission angle not larger than 30°, and said light absorbing film has a film size 10% larger than that of a cross section of a laser beam of said VCSEL diode that is intercepted by said light absorbing film.

5. The infrared emitter package as claimed in claim 1, wherein said header plateau of said TO-can unit further includes a top cap that is attached to said top side of said header plateau to protect said IR emitting unit, and said top cap has a top window opening allowing light to emit outwardly.

6. The infrared emitter package as claimed in claim 5, wherein said top cap further has a transparent plate disposed on said top window opening as protection against contamination from external environment.

7. The infrared emitter package as claimed in claim 5, which is adapted to be used in a non-dispersive infrared (NDIR) sensor, wherein said IR emitting unit emits radiation containing a signature wavelength of a gas to be detected by the NDIR sensor, said top cap further having a lens that is disposed in said top window opening and that is transparent to the signature wavelength of the gas to be detected to collimate and/or focus the signature wavelength.
